(19) United States
(12) Patent Application Publication
(10) Pub. No.: US 2006/0046414 A1
(43) Pub. Date: Mar. 2, 2006

(54) Method for producing a thermoelement

(76) Inventor: Thorsten Pannek, Stuttgart (DE)

Correspondence Address: KENYON & KENYON, ONE BROADWAY, NEW YORK, NY, 10004, US

(21) Appl. No.: 11/201,850

(22) Filed: Aug. 10, 2005

(30) Foreign Application Priority Data
Sep. 1, 2004 (DE) 102004042275.3

(51) Int. Cl. H01L 21/331

(52) U.S. Cl. 438/369

(57) ABSTRACT

A method for producing a thermoelement, in which a first and a second undoped thermoleg are generated on the surface of a substrate, a first resist mask is applied in such a way that the first thermoleg is not covered by it and the second thermoleg is covered by it, doping of the first thermoleg takes place, an at least partial removal of the first resist mask takes place, so that at least the second thermoleg is no longer covered by it, a second resist mask is applied in such a way that the first thermoleg is covered by it and the second thermoleg is not covered by it, doping of the second thermoleg takes place, an at least partial removal of the second resist mask takes place, so that at least the first thermoleg is no longer covered by it, and a connection of the first and the second thermoleg takes place by an electrically conductive material, what is involved being in the doping of the first thermoleg, an n-doping, and in the doping of the second thermoleg, a p-doping, or in the doping of the first thermoleg, a p-doping, and in the doping of the second thermoleg, an n-doping.

### BACKGROUND INFORMATION

In order to produce IR sensors in silicon micromechanics on a thermocouple basis, normally thermoelements are patterned as thin layers on diaphragms that are just as thin. To produce the thermoelements, doped polycrystalline silicon (poly-Si) and aluminum (Al), may be used, for example. In this context, however, the aluminum scarcely contributes to the thermoelectric power. The thermoelectric power of the poly-Si is a function of its doping. In order to improve the thermoelectric power of the thermoelement, instead of the aluminum, for example, an additional poly-Si layer is used. For maximum thermoelectric power, the two poly-Si thermolegs have to be of different types (p-type and n-type).

In order to produce such a thermoelement having p-doped and n-doped poly-Si thermolegs, it is known that one may first deposit poly-Si over the whole surface and dope after that, for instance, using an implantation method. In the already doped state, then, the first thermoleg is patterned from the whole-surface deposited and doped poly-Si layer. Now, in order to be able to pattern the second thermoleg without removing the first one in the process, an intermediary oxide has to be inserted as an etch stop. This is opened in the contact area of the two poly-Si thermolegs. Thereafter, the second thermoleg is deposited, doped (e.g. by implantation) and is patterned. Typically, the two thermolegs are connected by a metal bridge.

### SUMMARY OF THE INVENTION

The present invention relates to a method for producing a thermoelement, in which
a first and a second undoped thermoleg is generated on the surface of a substrate,
a first resist mask is applied in such a way that the first thermoleg is not covered by it and the second thermoleg is covered by it,
doping of the first thermoleg takes place,
an at least partial removal of the first resist mask takes place, so that at least the second thermoleg is no longer covered by it,
a second resist mask is applied in such a way that the first thermoleg is covered by it and the second thermoleg is not covered by it,
doping of the second thermoleg takes place,
an at least partial removal of the second resist mask takes place, so that at least the first thermoleg is no longer covered by it, and
connection of the first and the second thermoleg takes place by an electrically conductive material, what may be involved being
in the doping of the first thermoleg, an n-doping, and in the doping of the second thermoleg, a p-doping, or
in the doping of the first thermoleg, a p-doping, and in the doping of the second thermoleg, an n-doping.

This provides a simple possibility for producing a thermoelement, which stands out particularly by having a low number of working steps.

One advantageous embodiment of the present invention is characterized in that the first and second thermolegs are generated on the substrate surface by whole-surface depositing of the material on which the thermolegs are based on the substrate surface, and subsequent patterning. The whole-surface depositing is especially simple to carry out. In the patterning, for example, one may resort to known etching methods.

One advantageous embodiment of the present invention is characterized in that polycrystalline silicon is involved as the material on which the first and second thermolegs are based. This material is cost-effectively available. Instead of silicon, silicon germanium (SiGe) may also be used. SiGe is also available as a polycrystalline material.

One advantageous embodiment of the present invention is characterized in that a complete removal of the first resist mask is performed. This being the case, no remnants of resist remain to interfere with later production steps.

One advantageous embodiment of the present invention is characterized in that a complete removal of the second resist mask is carried out.

One advantageous embodiment of the present invention is characterized in that the connection of the first and the second thermoleg is accomplished by a bridge made of aluminum or titanium.

One advantageous embodiment of the present invention is characterized in that the surface of the substrate is made of SiO₂.

One advantageous embodiment of the present invention is characterized in that a silicon wafer is involved as the substrate, which is coated by the layer sequence SiO₂—
Si₃N₄—SiO₂.

As a result of its small size, as well as its suitability for production in large numbers of pieces, the thermoelement, according to the present invention, may advantageously be used in carbon dioxide sensors, which monitor the carbon dioxide content of the air in motor vehicles.

The present invention also relates to a thermoelement produced by the methods described. The advantageous embodiments of the method according to the present invention naturally also manifest themselves as advantageous embodiments of the thermoelements according to the present invention, and vice versa.

### BRIEF DESCRIPTION OF THE DRAWINGS

FIG. 1 shows the construction of an infrared sensor.

FIG. 2 shows the construction of a thermoelement known from the related art.

FIGS. 3a, 3b, 4, 5 and 6 show various method states in the production of the thermoelement.

### DETAILED DESCRIPTION

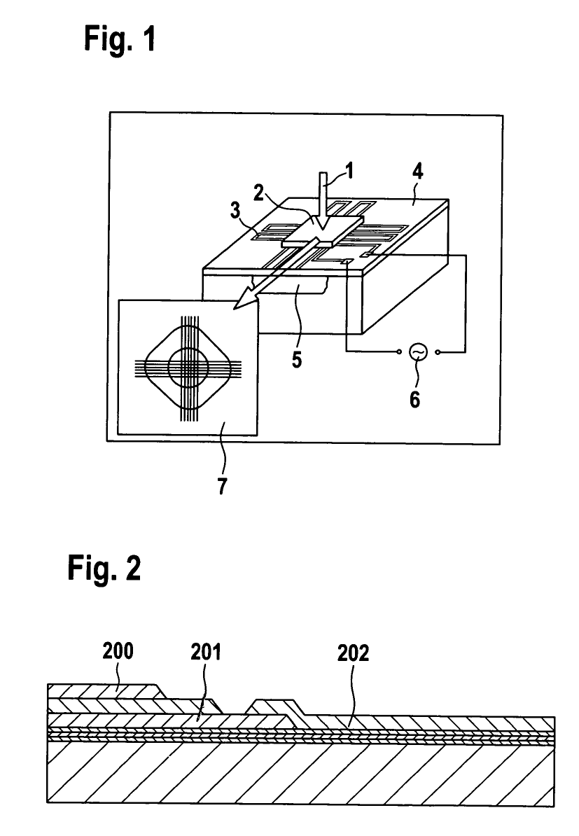

FIG. 1 shows an infrared sensor in silicon micromechanics that is known from the related art. In this context, the number 1 characterizes the incident infrared radiation having a specific wavelength. The number 2 characterizes a broadband absorption layer which covers thermoelement 3 at the hot contacts. The thermoelements are applied on a diaphragm 4 which covers a hollow space or cavity 5. The number 6 characterizes the thermovoltage picked off. In diagram 7, in the left lower corner, there is plotted an ascertained spatial temperature curve over the diaphragm.

FIG. 2 shows the construction of a thermoelement constructed according to a method known from the related art, whose production was described in the section “Background Information”. In this context, the following identifications hold:
200=n-poly-Si thermoelement,
201=p-poly-Si thermoelement,
202=intermediate oxide as etch stop.

The present invention makes it possible to make available both thermolegs by just one poly-Si deposit process and subsequent patterning. The intermediate oxide, which does not fulfill any function in the sensor (since, at this location, no insulation is required) may be omitted. That saves working steps, and costs are reduced.

The patterning of the two thermolegs is performed in the undoped state, that is, both thermolegs are produced from a whole-surface applied poly-Si. Thereafter, using two resist masks, each thermoleg is selectively doped and annealed. An implantation method may be used as the doping method.

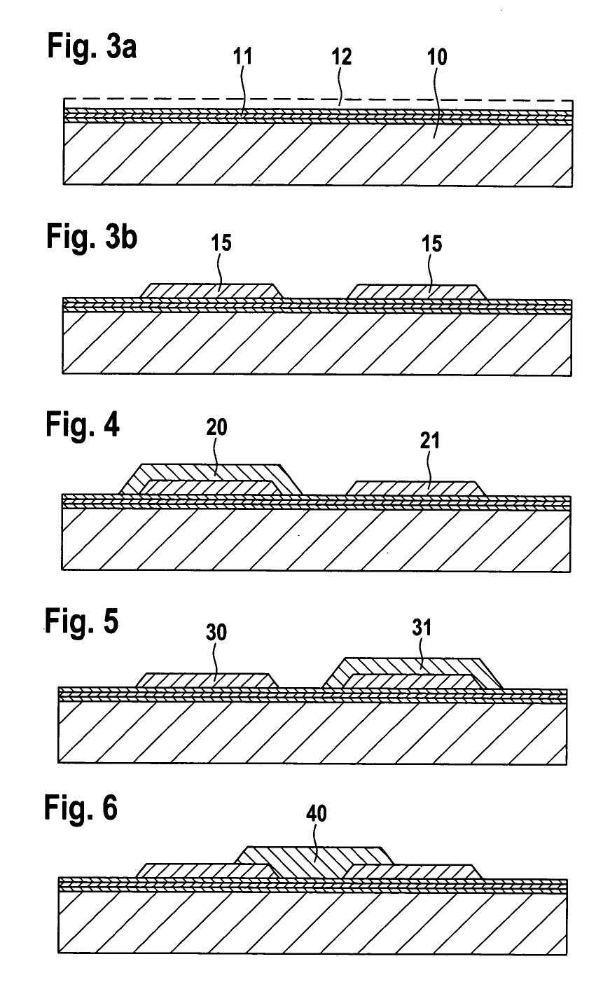

The sequence of the method according to the present invention is shown below in the light of FIGS. 3 to 6.

FIG. 3a shows a wafer 10 on which there is an ONO diaphragm. By the concept ONO diaphragm, one means the layer sequence SiO₂—Si₃N₄—siO₂. Now, on this diaphragm 11, over the whole surface, an undoped poly-Si layer is deposited. This is drawn in in FIG. 3a with a broken line and designated as 12. Instead of poly-Si, other semiconducting materials, such as SiGe, or compounds based on bismuth or antimony may be used.

FIG. 3b shows the two thermolegs 15 patterned from the poly-Si layer. The thermolegs are not yet connected at this stage of the method.

After that, as shown in FIG. 4, one of the two thermolegs is covered by a resist mask 20. It is also possible to cover the rest of the wafer, that is not covered by poly-Si, by the resist mask. Subsequently, a full surface implantation takes place. This may come about by incorporating atoms or ions, as well as by using high-energy radiation. Because of the resist mask, the implantation acts only on leg 21 that is not covered by the resist mask. Because of the implantation and a subsequent activation, the poly-Si of this leg is converted to n-poly-Si. After that, resist mask 20 is removed, and the poly-Si under it is annealed.

Subsequently, as shown in FIG. 5, the right thermoleg, that is now doped, is protected by a resist mask 31. Here too, the resist mask may also extend to parts of the wafer not covered by poly-Si. By using a whole-surface implantation method, left thermoleg 30 is now implanted, and a conversion takes place of poly-Si to p-poly-Si.

The resist is removed again and the poly-Si is annealed. Consequently, the second thermoleg was doped selectively.

It should be pointed out that, of course, the sequence of the doping may also be reversed, that is, first there is a p-doping and then there is an n-doping.

Subsequently, as shown in FIG. 6, the two thermolegs are connected to each other by a bridge 40 (e.g. made of metals such as Al or Ti).

What is claimed is:

1. A method for producing a thermoelement, comprising:
generating a first and a second undoped thermoleg on a surface of a substrate;
applying a first resist mask in such a way that the first thermoleg is not covered by it and the second thermoleg is covered by it;
doping the first thermoleg;
performing an at least partial removal of the first resist mask, so that at least the second thermoleg is no longer covered by it;
applying a second resist mask in such a way that the first thermoleg is covered by it and the second thermoleg is not covered by it;
doping the second thermoleg;
performing an at least partial removal of the second resist mask, so that at least the first thermoleg is no longer covered by it; and
making a connection of the first thermoleg and the second thermoleg using an electrically conductive material,
wherein one of:
(a) the first thermoleg is n-doped, and the second thermoleg is p-doped, and
(b) the first thermoleg is p-doped, and the second thermoleg is n-doped.

2. The method according to claim 1, wherein the first and second thermolegs are generated on the substrate surface by whole-surface depositing of a material on which the first and second thermolegs lie on the substrate surface, and subsequent patterning.

3. The method according to claim 1, wherein one of polycrystalline silicon and silicon-germanium is used as a material on which the first and second thermolegs are based.

4. The method according to claim 1, wherein a complete removal of the first resist mask takes place.

5. The method according to claim 1, wherein a complete removal of the second resist mask takes place.

6. The method according to claim 1, wherein the connection of the first and second thermolegs is made by a bridge made of one of aluminum and titanium.

7. The method according to claim 1, wherein the surface of the substrate is made of SiO₂.

8. The method according to claim 7, wherein a silicon wafer is used as the substrate, which is coated by a layer sequence SiO₂—Si₃N₄—SiO₂.

9. A thermoelement produced by the method according to claim 1.

10. The method according to claim 1, wherein the thermoelement is part of a carbon dioxide sensor for ascertaining the carbon dioxide concentration in the air in a passenger compartment of a motor vehicle.

11. A carbon dioxide sensor for ascertaining a carbon dioxide concentration in the air in a passenger compartment of a motor vehicle, the sensor including a thermoelement produced by the method according to claim 1.
